(19) United States
(12) Patent Application Publication
(10) Pub. No.: US 2025/0141134 A1
(43) Pub. Date: May 1, 2025

(54) MULTIPLE SLOT CARD EDGE CONNECTOR

(71) Applicant: Intel Corporation, Santa Clara, CA (US)

(72) Inventors: Xiang LI, Portland, OR (US); George VERGIS, Portland, OR (US); James A. McCALL, Portland, OR (US); Yanjie ZHU, Folsom, CA (US)

(21) Appl. No.: 19/004,170

(22) Filed: Dec. 27, 2024

(51) Int. Cl. H01R 12/72; H01R 13/02; H05K 1/18

(52) U.S. Cl. CPC H01R 12/721; H01R 13/02; H05K 1/181; H05K 2201/10159; H05K 2201/10189; H05K 2201/10734

(57) ABSTRACT

A multi-slot connector having reduced DIMM-to-DIMM pitch distances can support up to 64 memory channels for next generation DDR (double data rate) technology, including DDR6. To support the increase in memory channels, while compensating for limited form factor motherboards, the multi-slot connector includes two or more slots for devices, such as DIMMs, to connect to a motherboard or other platform. Reduced pitch distances between the DIMMs, shortened connector pins, thinner contacts, and complementary reduced pitch distances in a ball grid array (BGA) used to connect to the motherboard or other platform, provides a compact multi-slot connector that can support up to 64 memory channels with improved performance characteristics. An optional cooling device can be employed between the slots as needed to maintain optimal performance.

### FIELD

This disclosure relates to connectors for coupling modules (such as memory modules) or devices with a printed circuit board such as a motherboard, and more particularly, to a connector having multiple slots coupling multiple modules or devices with a printed circuit board.

### BACKGROUND

Various technologies exist for connecting devices, such as cards and modules, with a printed circuit board (PCB), such as a motherboard (MB). While it is possible to couple electronic components directly to an MB, it is common to use a connector between the MB and the card or module to enable removably coupling the card or module with the MB.

A Double Data Rate 5 (DDR5) Dual in-line Memory Module (DIMM) connector is a traditional edge card connector in which the DIMM is inserted into a single connector slot. The connector pins are spring loaded connector to ensure connection with the edges of the gold finger contacts. The DDR5 connector is typically soldered on the MB through the surface mount technology (SMT) pad(s). The DDR5 connector supports a DIMM to DIMM pitch size of 7.6 mm due to MB form factor limits. As a result, the total number of memory channels are limited.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing at least one implementation of the invention that includes one or more particular features, structures, or characteristics. Thus, phrases such as “in one embodiment” or “in an alternate embodiment” appearing herein describe various embodiments and implementations of the invention, and do not necessarily all refer to the same embodiment. However, they are also not necessarily mutually exclusive.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is noted that the views, block diagrams and the like in the drawings are illustrative and not drawn to scale. For example, the relative dimensions and placements for some of the components in the views and block diagrams herein are exaggerated for clarity and point of illustration. For example, one having skill in the art will recognize the components in an actual implementation will generally have dimensions and thicknesses that are different than that shown in the Figures herein (e.g., substantially smaller and/or thinner), or be placed in a manner that is different from what is represented in a block diagram or other illustration.

FIG. 1A is a cross-sectional side view of an example of a device for coupling with a motherboard using a connector having multiple slots (hereafter referred to as a multi-slot connector) in accordance with embodiments described herein;

FIG. 1B is a plan view of a partial ball grid array for a multi-slot connector, as illustrated in FIG. 1A, in accordance with embodiments described herein;

FIG. 2A is an illustration of prior art DDR5 single slot connectors capable of supporting a maximum of 16 channels, as described herein;

FIG. 2B is an illustration of multi-slot connectors as in FIGS. 1A and 1B, capable of supporting a maximum of 64 channels, in accordance with embodiments described herein;

FIG. 3 is a plan view of a partial reference footprint of a multi-slot connector, as in FIGS. 1A and 1B, in accordance with embodiments described herein;

FIG. 4 is a plan view of a system supporting 64 memory channels using multiple multi-slot connectors, as in FIGS. 1A, 1B, 2B, and 3, in accordance with embodiments described herein;

FIG. 5 is a graph illustrating an example comparison of far end crosstalk (FEX) between a single slot connector and a multi-slot connector, as in FIGS. 1A, 1B, 2B, and 3, in accordance with embodiments described herein; and

FIG. 6 depicts a system in which multi-slot connector, as in FIGS. 1A, 1B, 2B, and 3, may be implemented, the multi-slot connector having been formed in accordance with embodiments described herein.

### DETAILED DESCRIPTION

Conventional card edge connectors, such as Double Data Rate Version 5 (DDR5) connectors formed in accordance with memory technology standard specifications originally published by JEDEC (Joint Electronic Device Engineering Council) in October 2013, or with other technologies based on derivatives or extensions of such specifications, are limited in the number of memory channels they can support. Currently, DDR5 connectors are formed with a 7.6 mm DIMM to DIMM pitch. Due to MB form factor limits and the physical distances required for DDR5 connectors, the total memory channels that DDR5 connectors can support are limited.

With the transition to DDR6 standards and higher bandwidth, efforts to increase the number of memory channels include the use of half-width DIMMs. While half-width DIMMs can increase the number of memory channels from 16 to 32, it still falls short of the goal of increasing the number of memory channels to 64. Other proposals to increase the number of memory channels include using compression mount technology (CMT) connectors that support compressed attachment memory modules (CAMM). While a CAMM-based solution can increase the number of memory channels to 64, it also requires the use of retention structures that raise reliability concerns. For this reason, CAMM-based solutions have received push-back from JEDEC and industry stakeholders. In particular, Original Equipment Manufacturers (OEMs) and Original Design Manufacturers (ODM) and memory vendors remain committed to more conventional vertical connector solutions compatible with the standard vertical DDR5 connectors in use today.

To address this challenge, embodiments of a multiple slot card edge connector (hereafter referred to simply as a multi-slot connector) enable up to 64 memory channels to support DDR6 and future memory technology standard specifications.

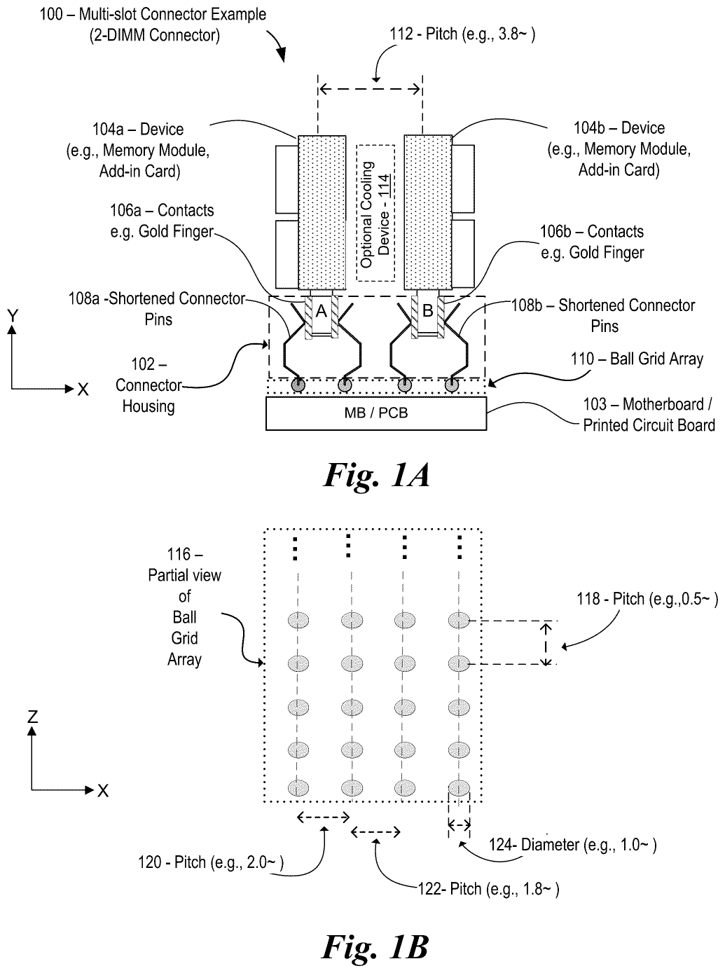

FIG. 1A is a cross-sectional side view of an example of devices 104a, 104b, for coupling with a motherboard using a connector having multiple slots 100 (hereafter referred to as a multi-slot connector) in accordance with embodiments described herein. In contrast with a conventional DDR5 single-slot connector, the multi-slot connector supports two or more of the devices 104a, 104b, such as two DIMMs, for insertion into separate slots, e.g., slot A and slot B, using a DIMM-to-DIMM reduced pitch distance (the physical distance measured from the center of one component to an adjacent component, hereafter referred to as just pitch) 112 that is approximately half as wide (e.g., 3.8 mm) as a conventional DIMM-to-DIMM pitch (currently, 7.6 mm), that is required when using DDR5 single-slot connectors. The multi-slot connector 100 implemented in accordance with the described embodiments significantly improves memory channel capacity for next generation DDR technology, including DDR6.

In the illustrated embodiment, both devices 104a, 104b, including memory modules (e.g., DIMMs, CAMMs or an add-in card (AIC)), can be attached to a PCB or MB 103 using a multi-slot connector 100. In one embodiment, multi-slot connector 100 includes two or more slots (e.g., slot A and slot B). In order to support the reduced pitch 112, a ball grid array (BGA) 110 footprint is used to attach the inserted devices 104a, 104b, to pairs of shortened connector pins 108a, 108b. In one embodiment, the shortened connector pins 108a, 108b have a reduced height to fit the tighter reduced pitch 112. For example, in one embodiment, the shortened connector pins have a reduced height of approximately 5-6 mm, as opposed to a standard connector pin height of over 6 mm. Multiple shortened connector pins 108a, 108b are aligned along the Z plane of the multi-slot connector 100 (not shown) to span the width of the of the inserted devices 104a, 104b, e.g., the width of the inserted DIMM devices.

In the illustrated embodiment in FIG. 1A, the pairs of shortened connector pins 108a, 108b are housed in a connector housing 102. The shortened connector pins 108a, 108b, include a bottom portion external to the housing that is in physical and electrical contact with a ball in the BGA 110. In turn, the BGA 110 is in physical and electrical contact with the MB/PCB 103 to which the inserted devices 104a, 104b, are being connected using the multi-slot connector 100.

The pairs of shortened connector pins 108a, 108b, also make contact with contacts 106a, 106b. The contacts 106a, 106b, are conductive contacts that can include pins, pads, traces, wires, terminals, leads, balls, screws, blades, or other contacts that enable formation of an electrical connection. In one embodiment, the conductive contact 106 can include a gold finger (GF) of a memory module (e.g., a DIMM). In one embodiment, the DIMM devices 104a, 104b, can have a step PCB. For this reason, the contacts (e.g., gold finger contacts) 106a, 106b corresponding to each pair of shortened connector pins 108a, 108b can be thinner than is typically the case so as to be compatible therewith (i.e., to avoid a tolerance issue).

In one embodiment, because the reduced pitch distances 112 can pose a thermal challenge during operation, some of the multi-slot connectors 100 can be used as single side components to provide enough space for air cooling in a system. In one embodiment, an optional cooling device 114 can be employed to increase thermal dissipation for high data rate operation. Embodiments employing the optional cooling device 114 can include a heat pipe or a vapor chamber for liquid cooling.

FIG. 1B is a plan view of a partial BGA 116, (aligned along the Z plane), for a multi-slot connector 100 as in FIG. 1A, in accordance with embodiments described herein. As shown, in support of maximizing the number of memory channels, one or more pitch distances for the BGA are reduced to complement the reduced DIMM-to-DIMM pitch 112 between devices 104a, 104b. For example, to complement pitch 112 of approximately 3.8 mm between the devices 104a, 104b inserted into the multi-slot connector 100, a first BGA pitch 120 between adjacent balls respectively connected to the left and right pins of a same pair of shortened connector pins, e.g., 108a, is reduced to approximately 2.0 mm, while a second BGA pitch 122 between adjacent balls connected to a right connector pin of one pair of shortened connector pins 108a and a left connector pin of a neighboring pair of shortened connector pins 108b, is reduced to approximately 1.8 mm. When added together, the first BGA pitch 120 and the second BGA pitch 122 equal the reduced pitch 112 between the inserted devices 104a, 104b.

In one embodiment, the diameter 124 of each ball in the BGA 116 is approximately 1.0 mm. A third reduced BGA pitch 118 (e.g., 0.5 mm) is used between the balls of the BGA 116 from one row of balls to the next row of balls. The diameter 124 combines with the first 120, second 122 and third 118 reduced BGA pitches to enable greater density to increase memory channel capacity.

Although the illustrated multi-slot connector 100 in FIGS. 1A-1B has two slots, slot A and slot B, other embodiments include multi-slot connectors having more than two slots, including a 4 slot multi-slot connector to support a 4-DIMM connector.

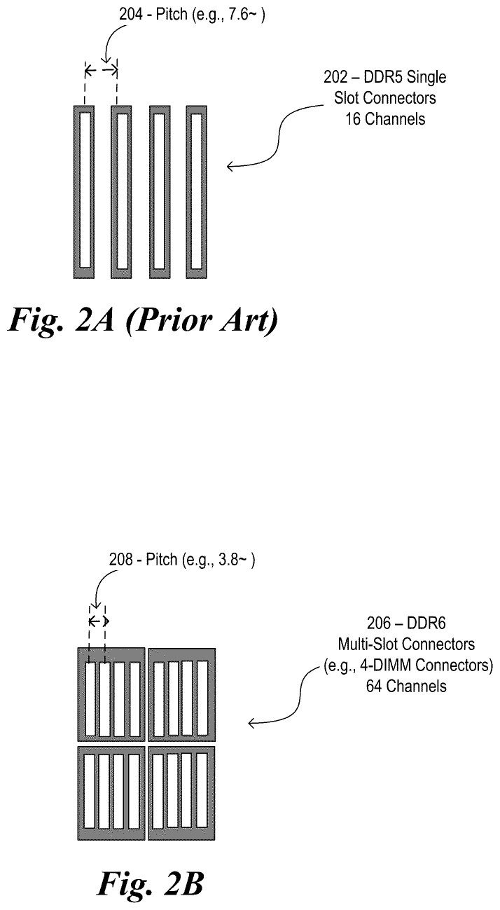

FIG. 2A is an illustration of prior art DDR5 single slot connectors 202 capable of supporting a maximum of 16 channels, as described herein. As shown, the pitch 204 between each single slot connector 202 is approximately 7.6 mm.

In contrast, FIG. 2B is an illustration of DDR6 multi-slot connectors 100/206 as in FIGS. 1A and 1B, capable of supporting a maximum of 64 channels, in accordance with embodiments described herein. As shown, four 4-DIMM multi-slot connectors 206 can support 64 channels, with the reduced pitch 112 of approximately 3.8 mm between each device 104a, 104b, inserted into the multi-slot connectors 100/206, and corresponding reduced BGA pitches 120, 122 and 118 and ball diameter 124 as described with reference to FIG. 1B.

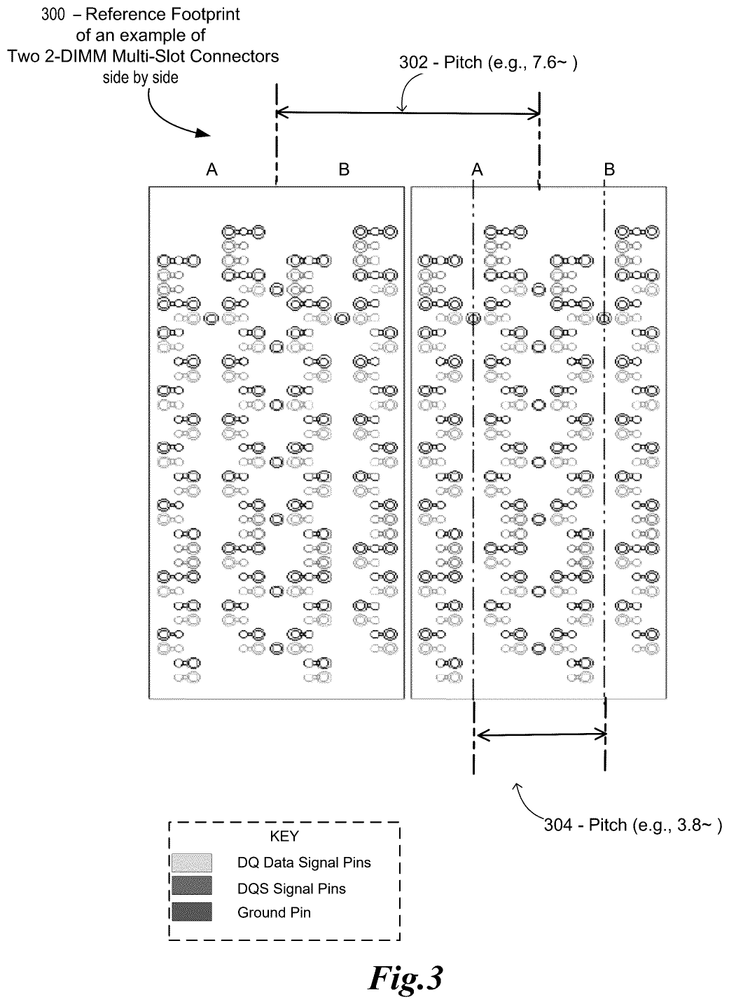

FIG. 3 is a plan view of a partial reference footprint 300 of two adjacent 2-DIMM multi-slot connectors 100, as in FIGS. 1A and 1B, for supporting up to 64 memory channels in accordance with embodiments described herein. In one embodiment, as shown in the reference footprint 300, the reduced pitch 304 between footprints for the DIMM devices 104a, 104b inserted into the multi-slot connector 100 is approximately 3.8. The reduced pitch 304 of 3.8 spans an overall pitch 302 of approximately 7.6 between footprints for adjacent 2-DIMM multi-slot connectors 100, thereby doubling the number of devices 104a, 104b that can be accommodated as compared to the footprint of four conventional DDR5 single-slot connectors.

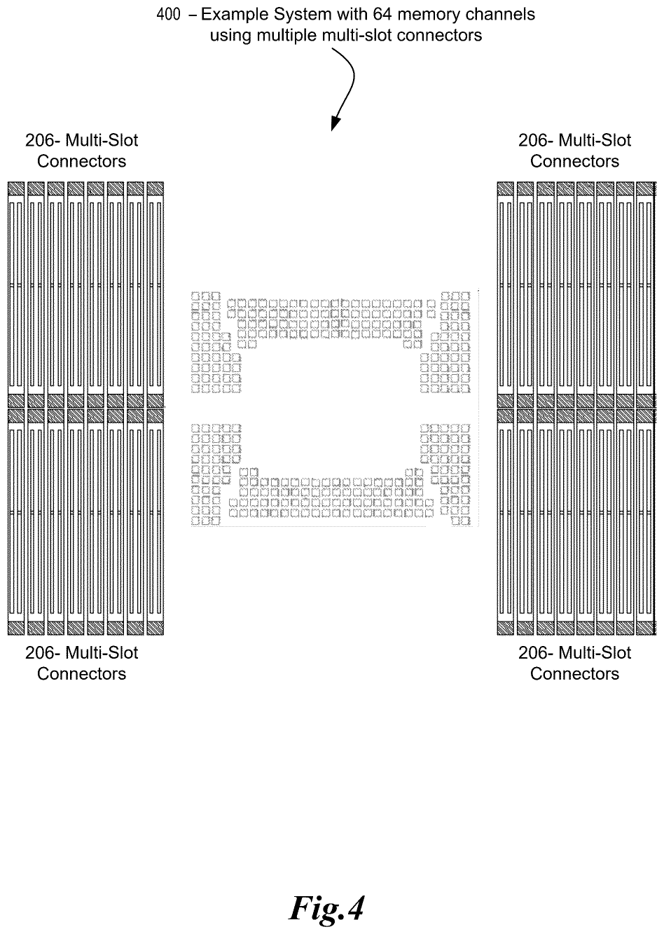

FIG. 4 is a plan view of a system 400 supporting 64 memory channels using multiple multi-slot connectors 100, 206, as introduced in FIGS. 1A, 1B, and 2B in accordance with embodiments described herein. As shown, eight sets of multi-slot connectors 206 arranged in four groups, provide the system 400 with capacity for up to 64 memory channels.

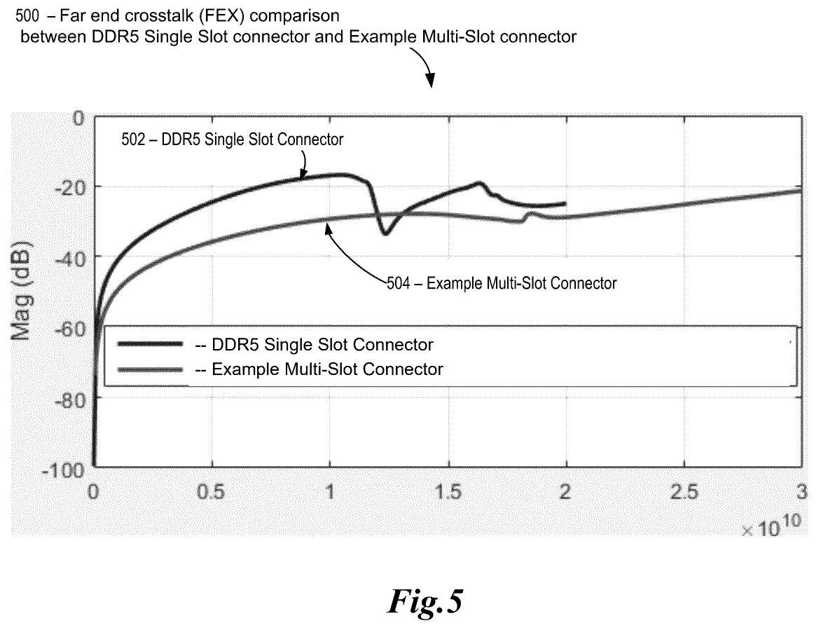

FIG. 5 is a graph illustrating an example comparison of far end crosstalk (FEXT) between a single slot connector and a multi-slot connector, as in FIGS. 1A, 1B, 2B, and 3, in accordance with embodiments described herein. As shown in the example comparison between prior art connector (e.g., a DDR5 connector) and an embodiment of a multi-slot connector 100 as described herein, the FEXT crosstalk is reduced when using the multi-slot connector 100. During operation at 5 GHz, embodiments of a multi-slot connector 100 shows 15 dB improvement in FEXT crosstalk due to reduced pitch distances 112, 118, 120 and 122, because the signal to ground is closer, as well as due to the use of shortened connector pins 108a, 108b.

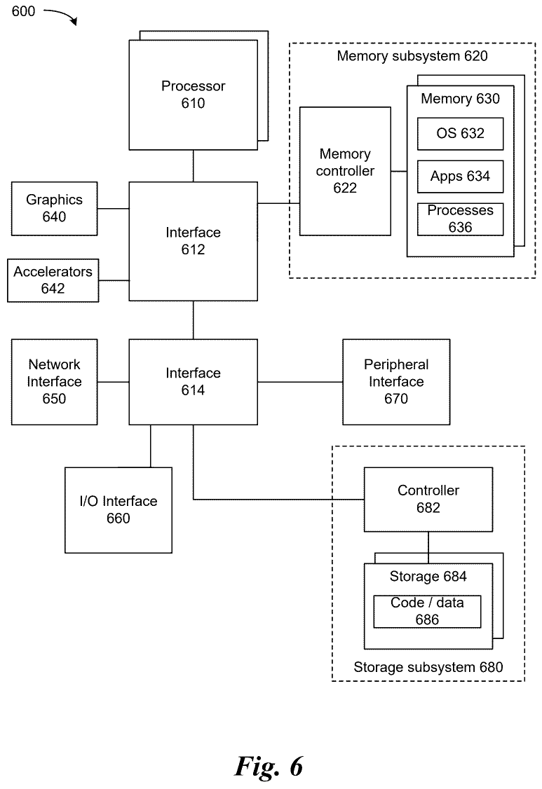

FIG. 6 depicts a system 600 in which embodiments of a multi-slot connector 100 can be implemented. The system 600 includes processor 610, which provides processing, operation management, and execution of instructions for system 600. Processor 610 can include any type of microprocessor, central processing unit (CPU), graphics processing unit (GPU), XPU, processing core, or other processing hardware to provide processing for system 600, or a combination of processors. An XPU can include one or more of: a CPU, a graphics processing unit (GPU), general purpose GPU (GPGPU), and/or other processing units (e.g., accelerators or programmable or fixed function FPGAs). Processor 610 controls the overall operation of system 600, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 600 includes interface 612 coupled to processor 610, which can represent a higher speed interface or a high throughput interface for system components that needs higher bandwidth connections, such as memory subsystem 620 or graphics interface components 640, or accelerators 642. Interface 612 represents an interface circuit, which can be a standalone component or integrated onto a processor die. Where present, graphics interface 640 interfaces to graphics components for providing a visual display to a user of system 600. In one example, graphics interface 640 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 640 generates a display based on data stored in memory 630 or based on operations executed by processor 610 or both. In one example, graphics interface 640 generates a display based on data stored in memory 630 or based on operations executed by processor 610 or both.

Accelerators 642 can be a programmable or fixed function offload engine that can be accessed or used by a processor 610. For example, an accelerator among accelerators 642 can provide compression (DC) capability, cryptography services such as public key encryption (PKE), cipher, hash/authentication capabilities, decryption, or other capabilities or services. In some embodiments, in addition or alternatively, an accelerator among accelerators 642 provides field select controller capabilities as described herein. In some cases, accelerators 642 can be integrated into a CPU socket (e.g., a connector to a motherboard or circuit board that includes a CPU and provides an electrical interface with the CPU). For example, accelerators 642 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs). Accelerators 642 can provide multiple neural networks, CPUs, processor cores, general purpose graphics processing units, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 620 represents the main memory of system 600 and provides storage for code to be executed by processor 610, or data values to be used in executing a routine. Memory subsystem 620 can include one or more memory devices 630 such as read-only memory (ROM), flash memory, one or more varieties of random access memory (RAM) such as DRAM, or other memory devices, or a combination of such devices. Memory 630 stores and hosts, among other things, operating system (OS) 632 to provide a software platform for execution of instructions in system 600. Additionally, applications 634 can execute on the software platform of OS 632 from memory 630. Applications 634 represent programs that have their own operational logic to perform execution of one or more functions. Processes 636 represent agents or routines that provide auxiliary functions to OS 632 or one or more applications 634 or a combination. OS 632, applications 634, and processes 636 provide software logic to provide functions for system 600. In one example, memory subsystem 620 includes memory controller 622, which is a memory controller to generate and issue commands to memory 630. It will be understood that memory controller 622 could be a physical part of processor 610 or a physical part of interface 612. For example, memory controller 622 can be an integrated memory controller, integrated onto a circuit with processor 610.

While not specifically illustrated, it will be understood that system 600 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, system 600 includes interface 614, which can be coupled to interface 612. In one example, interface 614 represents an interface circuit, which can include standalone components and integrated circuitry. In one example, multiple user interface components or peripheral components, or both, couple to interface 614. Network interface 650 provides system 600 with the ability to communicate with remote devices (e.g., servers or other computing devices) over one or more networks. Network interface 650 can include an Ethernet adapter, wireless interconnection components, cellular network interconnection components, USB (universal serial bus), or other wired or wireless standards-based or proprietary interfaces. Network interface 650 can transmit data to a device that is in the same data center or rack or a remote device, which can include sending data stored in memory. Network interface 650 can receive data from a remote device, which can include storing received data into memory. Various embodiments can be used in connection with network interface 650, processor 610, and memory subsystem 620.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include any hardware interface not specifically mentioned above. Peripherals refer generally to devices that connect dependently to system 600. A dependent connection is one where system 600 provides the software platform or hardware platform or both on which operation executes, and with which a user interacts.

In one example, system 600 includes storage subsystem 680 to store data in a nonvolatile manner. In one example, in certain system implementations, at least certain components of storage 680 can overlap with components of memory subsystem 620. Storage subsystem 680 includes storage device(s) 684, which can be or include any conventional medium for storing large amounts of data in a nonvolatile manner, such as one or more magnetic, solid state, or optical based disks, or a combination. Storage 684 holds code or instructions and data 686 in a persistent state (e.g., the value is retained despite interruption of power to system 600). Storage 684 can be generically considered to be a “memory,” although memory 630 is typically the executing or operating memory to provide instructions to processor 610. Whereas storage 684 is nonvolatile, memory 630 can include volatile memory (e.g., the value or state of the data is indeterminate if power is interrupted to system 600). In one example, storage subsystem 680 includes controller 682 to interface with storage 684. In one example controller 682 is a physical part of interface 614 or processor 610 or can include circuits or logic in both processor 610 and interface 614.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). Another example of volatile memory includes cache or static random access memory (SRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/output version 2, JESD229-2 originally published by JEDEC in August 2014, HBM (High Bandwidth Memory, JESD325, originally published by JEDEC in October 2013, LPDDR5 (currently in discussion by JEDEC), HBM2 (HBM version 2), currently in discussion by JEDEC, or others or combinations of memory technologies, and technologies based on derivatives or extensions of such specifications. The JEDEC standards are available at www.jedec.org.

A non-volatile memory (NVM) device is a memory whose state is determinate even if power is interrupted to the device. In some embodiments, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), Intel® Optane™ memory, NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 600. More specifically, power source typically interfaces to one or multiple power supplies in system 600 to provide power to the components of system 600. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 600 can be implemented using interconnected compute sleds of processors, memories, storages, network interfaces, and other components. High speed interconnects can be used such as PCIe, Ethernet, or optical interconnects (or a combination thereof).

Embodiments herein may be implemented in various types of computing and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. It is noted that hardware, firmware and/or software elements may be collectively or individually referred to herein as “module,” or “logic.” A processor can be one or more combination of a hardware state machine, digital control logic, central processing unit, or any hardware, firmware and/or software elements.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences of steps may also be performed according to alternative embodiments. Furthermore, additional steps may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”′

Flow diagrams as illustrated herein provide examples of sequences of various process actions. The flow diagrams can indicate operations to be executed by a software or firmware routine, as well as physical operations. In some embodiments, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is noted that the views, block diagrams and the like in the drawings are illustrative and not drawn to scale. For example, the relative dimensions and placements for some of the components in the views and block diagrams herein are exaggerated for clarity and point of illustration. For example, one having skill in the art will recognize the components in an actual implementation will generally have dimensions and thicknesses that are different than that shown in the Figures herein (e.g., substantially smaller and/or thinner), or be placed in a manner that is different from what is represented in a block diagram or other illustration.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, and so forth.

Illustrative examples of the devices, systems, and methods disclosed herein are provided below. An embodiment of the devices, systems, and methods may include any one or more, and any combination of, the examples described below.
Example 1 is a method, system, apparatus or computer-readable medium in which an embodiment of a multiple slot card edge connector includes a connector to connect two or more first devices to a second device in which the connector has two or more slots in which to insert the two or more first devices, including a first slot and a second slot, and two of the two or more first devices inserted into respective first and second slots have a reduced pitch, and an electrical connection between the first devices and the second device, wherein the electrical connection includes connector pins connecting inserted first devices to a ball grid array (BGA) in which balls of the BGA have BGA pitches to complement the reduced pitch between the first devices inserted into the respective first and second slots.
Example 2 is the method, system, apparatus or computer-readable medium as in Example 1, wherein the reduced pitch does not exceed 3.8 mm.
Example 3 is the method, system, apparatus or computer-readable medium as in any of Examples 1 and 2, wherein the two or more first devices include any of a dual in-line memory module (DIMM), a compression attached memory module (CAMM) and an add-in card (AIC).
Example 4 is the method, system, apparatus or computer-readable medium as in any of Examples 1, 2 and 3, wherein the second device is a printed circuit board (PCB), including a motherboard (MB).
Example 5 is the method, system, apparatus or computer-readable medium as in any of Examples 1, 2, 3 and 4, wherein the reduced pitch of the first devices inserted into the respective first and second slots of the connector and the BGA pitches complementing the reduced pitch are consistent with a specification of the Joint Electronic Device Engineering Council Double Data Rate (DDR).
Example 6 is the method, system, apparatus or computer-readable medium as in any of Examples 1, 2, 3, 4 and 5, wherein the connector pins include a pair of shortened connector pins for each of the two or more slots of the connector, each shortened connector pin not to exceed 6 mm in height, with one end of each shortened connector pin connected to a ball in the BGA array.
Example 7 is the method, system, apparatus or computer-readable medium as in any of Examples 1, 2, 3, 4, 5 and 6, wherein the BGA array comprises balls not to exceed 1 mm in diameter, and the BGA pitches include a first BGA pitch between adjacent balls respectively connected to a left pin and right pin of a same pair of connector pins, and a second BGA pitch between adjacent balls connected to a right pin of one pair of connector pins and a left pin of a neighboring pair of connector pins, wherein the first BGA pitch is not to exceed 2.0 mm and the second BGA pitch is not to exceed 1.8 mm.
Example 8 is the method, system, apparatus or computer-readable medium as in any of Examples 1, 2, 3, 4, 5, 6 and 7, wherein the electrical connection further includes contacts on the first devices to make contact with the connector pins, the contacts including a gold finger of thinner depth to account for the two or more slots of the connector.

What is claimed is:

1. An apparatus comprising:
a connector to connect two or more first devices to a second device;
the connector having two or more slots in which to insert the two or more first devices, including a first slot and a second slot;
two of the two or more first devices inserted into respective first and second slots having a reduced pitch; and
an electrical connection between the first devices and the second device, wherein the electrical connection includes connector pins connecting inserted first devices to a ball grid array (BGA) in which balls of the BGA have BGA pitches to complement the reduced pitch between the first devices inserted into the respective first and second slots.

2. The apparatus of claim 1, wherein the reduced pitch does not exceed 3.8 mm.

3. The apparatus of claim 1, wherein the two or more first devices include any of a dual in-line memory module (DIMM), a compression attached memory module (CAMM) and an add-in card (AIC).

4. The apparatus of claim 1, wherein the second device is a printed circuit board (PCB), including a motherboard (MB).

5. The apparatus of claim 1, wherein the reduced pitch of the first devices inserted into the respective first and second slots of the connector and the BGA pitches complementing the reduced pitch are consistent with a specification of the Joint Electronic Device Engineering Council Double Data Rate (DDR).

6. The apparatus of claim 1, wherein the connector pins include a pair of shortened connector pins for each of the two or more slots of the connector, each shortened connector pin not to exceed 6 mm in height, with one end of each shortened connector pin connected to a ball in the BGA array.

7. The apparatus of claim 1, wherein the BGA array comprises balls not to exceed 1 mm in diameter, and the BGA pitches include:
a first BGA pitch between adjacent balls respectively connected to a left pin and right pin of a same pair of connector pins, and
a second BGA pitch between adjacent balls connected to a right pin of one pair of connector pins and a left pin of a neighboring pair of connector pins; and
wherein the first BGA pitch is not to exceed 2.0 mm and the second BGA pitch is not to exceed 1.8 mm.

8. The apparatus of claim 1, wherein the electrical connection further includes contacts on the first devices to make contact with the connector pins, the contacts including a gold finger of thinner depth to account for the two or more slots of the connector.

9. A system comprising:
two or more first devices;
a second device; and
a connector to connect the two or more first devices to the second device, the connector having two or more slots in which to insert the two or more first devices, including a first slot and a second slot;
the two or more first devices inserted into respective first and second slots having a reduced pitch; and
an electrical connection between the two or more first devices and the second device, wherein the electrical connection includes connector pins connecting inserted first devices to a ball grid array (BGA) in which balls of the BGA have BGA pitches to complement the reduced pitch of the first devices inserted into the respective first and second slots.

10. The system of claim 9, wherein the reduced pitch does not exceed 3.8 mm.

11. The system of claim 9, wherein the two or more first devices include any of a dual in-line memory module (DIMM), a compression attached memory module (CAMM) and an add-in card (AIC).

12. The system of claim 9, wherein the second device is a printed circuit board (PCB), including a motherboard (MB).

13. The system of claim 9, wherein the reduced pitch of the first devices inserted into the respective first and second slots of the connector and the BGA pitches complementing the reduced pitch are consistent with a specification of the Joint Electronic Device Engineering Council Double Data Rate (DDR).

14. The system of claim 9, wherein the connector pins include a pair of shortened connector pins for each of the two or more slots of the connector, each shortened connector pin not to exceed 6 mm in height, with one end of each shortened connector pin connected to a ball in the BGA array.

15. The system of claim 14, wherein the BGA array comprises balls not to exceed 1 mm in diameter, and the BGA pitches include:
a first BGA pitch between adjacent balls respectively connected to a left pin and right pin of a same pair of connector pins, and
a second BGA pitch between adjacent balls connected to a right pin of one pair of connector pins and a left pin of a neighboring pair of connector pins; and
wherein the first BGA pitch is not to exceed 2.0 mm and the second BGA pitch is not to exceed 1.8 mm.

16. The system of claim 9, wherein the electrical connection further includes contacts on the first devices to make contact with the connector pins, the contacts including a gold finger of thinner depth to account for the two or more slots of the connector.

17. A connector device comprising:
two or more slots in which to insert two or more first devices, including a first slot and a second slot;
two of the two or more first devices inserted into respective first and second slots having a reduced pitch; and
an electrical connection between the first devices and a second device, the electrical connection including connector pins to connect inserted first devices to a ball grid array (BGA) in which balls of the BGA have BGA pitches to complement the reduced pitch between the first devices inserted into the respective first and second slots.

18. The connector device of claim 17, wherein the two or more first devices include any of a dual in-line memory module (DIMM), a compression attached memory module (CAMM), and an add-in card (AIC).

19. The connector device of claim 17, wherein the second device is a printed circuit board (PCB), including a motherboard (MB).

20. The connector device of claim 17, wherein the reduced pitch of the first devices inserted into the respective first and second slots of the connector and the BGA pitches matching the reduced pitch are consistent with a specification of the Joint Electronic Device Engineering Council Double Data Rate (DDR).
